(19) United States
(12) Patent Application Publication
(10) Pub. No.: US 2013/0025646 A1
(43) Pub. Date: Jan. 31, 2013

(54) PHOTOVOLTAIC MODULE WITH IMPROVED DEAD CELL CONTACT

(71) Applicant: Scott Daniel Feldman-Peabody, Golden, CO (US)

(72) Inventor: Scott Daniel Feldman-Peabody, Golden, CO (US)

(73) Assignee: PRIMESTAR SOLAR, INC., Arvada, CO (US)

(21) Appl. No.: 13/192,578

(22) Filed: Jul. 28, 2011

(51) Int. Cl. H01L 31/05; H01L 31/18

(52) U.S. Cl. 136/244; 438/66; 257/E31.124

(57) ABSTRACT

The photovoltaic device can also include an insulating layer (e.g., an insulating material strip) beneath said first lead and said second lead, which may extend over the dead cell, extend over only a portion of the dead cell (i.e., the insulating layer does not extend over the entire width of the dead cell), or does not extend over the dead cell at all (e.g., ending at the scribe line separating the dead cell from the plurality of serially connected solar cells). When the insulating layer extends over at least a portion of the dead cell, the solder layer can extend over the insulating layer. Methods are also generally provided for manufacturing a photovoltaic device.

### FIELD OF THE INVENTION

The subject matter disclosed herein relates generally to the photovoltaic (PV) modules, and more particularly to an improved current collection between the dead cell and foil ribbon on PV modules.

### BACKGROUND OF THE INVENTION

Thin film photovoltaic (PV) modules (also referred to as “solar panels”) are gaining wide acceptance and interest in the industry. The PV modules are conventionally formed by deposition of various semiconductor materials and electrode layers as thin (generally recognized in the art as less than 10 microns) film layers on a glass substrate. The substrate then undergoes various processing steps, including laser scribing processes, to define and isolate individual cells, define a perimeter edge zone around the cells, and to connect the cells in series. These steps result in generation of a plurality of individual solar cells defined within the physical edges of the substrate.

Each solar cell is interconnected to the one next to it through a series of laser scribes and processing steps such that the back contact of one cell is the front contact for the cell next to it, and so forth. In a monolithically integrated solar module, the last cell is the front contact for the second to last cell, but has no neighboring cell to be its front contact. Accordingly, no current can be collected from this cell and it is known as the “dead” cell.

A well known method for collecting the charge from a PV module is to attach a strip of insulation (e.g., an insulating tape) lengthwise along the module across the cells. A conductive foil (e.g. a foil tape or ribbon) is then aligned and attached to the insulation tape. Bus bars (typically in the form of an adhesive bus tape) are then attached at opposite longitudinal ends of the module aligned with the first and last cells, respectively. The bus tapes cross over and attach to the foil layer, collect the current from the cells, and carries the current to the foil ribbon. The foil ribbon is separated in a junction box wherein leads are connected to the separated foil ends. The leads provide a means to connect the PV module to a load, other cells, an inverter, a grid, and so forth.

However, the use of a bus tape requires the dead cell on the module to be nearly as wide as every live cell in order to ensure adequate current collection. This relatively large area of the dead cell generates no current nor does it provide any extra voltage. Additionally, the electrical junction between the bus tapes and foil ribbon can fail, creating an open circuit that renders the PV module useless.

Accordingly, there exists an ongoing need in the industry for an improved, smaller, and/or more reliable electrical contact between the dead cell and foil ribbon that will reduce the surface area required by the dead cell.

### BRIEF DESCRIPTION OF THE INVENTION

Aspects and advantages of the invention will be set forth in part in the following description, or may be obvious from the description, or may be learned through practice of the invention.

Photovoltaic devices are generally provided that include a substrate, a solder layer, and an electrical connector. The substrate has a plurality of serially connected solar cells defined thereon, wherein the plurality of serially connected solar cells are positioned between a dead cell and a terminal cell for collecting the charge generated by the plurality of serially connected solar cells. The solder layer is applied along the dead cell and connected to a first lead. The solder layer generally includes a solder (e.g., at least one of tin, lead, antimony, bismuth, silver, or indium, which includes combinations thereof). The electrical connector (e.g., a bus tape) is applied along the terminal cell and connected to a second lead.

In one embodiment, the dead cell can define less surface area on the photovoltaic module than defined by an individual solar cell in the plurality of serially connected solar cells, and in certain embodiments, each individual solar cell can define a cell width that is less than a width defined by the dead cell. In one particular embodiment, the first lead and the second lead can be formed from a severed foil ribbon.

The photovoltaic device can also include an insulating layer (e.g., an insulating material strip) beneath said first lead and said second lead, which may extend over the dead cell, extend over only a portion of the dead cell (i.e., the insulating layer does not extend over the entire width of the dead cell), or does not extend over the dead cell at all (e.g., ending at the scribe line separating the dead cell from the plurality of serially connected solar cells). When the insulating layer extends over at least a portion of the dead cell, the solder layer can extend over the insulating layer.

Methods are also generally provided for manufacturing a photovoltaic device. The method can include applying a solder layer, connecting the solder layer to a first lead; and, connecting the terminal cell to an electrical connector to a second lead. The solder layer can generally be located on a dead cell positioned at an end of a plurality of serially connected solar cells defined on a substrate, wherein the plurality of serially connected solar cells are positioned between the dead cell and a terminal cell for collecting the charge generated by the plurality of serially connected solar cells, and, wherein the solder layer comprises a solder.

### BRIEF DESCRIPTION OF THE DRAWINGS

A full and enabling disclosure of the present invention, including the best mode thereof, is set forth in the specification, which makes reference to the appended drawings, in which:

FIG. 1 shows a cross-sectional view of an exemplary thin film photovoltaic device according to one embodiment;

FIG. 2 shows a blown-up section of the exemplary thin film photovoltaic device of FIG. 1;

FIG. 3 shows a top view of an exemplary thin film photovoltaic device defining a plurality of cells;

FIG. 4 shows a top view of the exemplary photovoltaic device of FIG. 3 having a solder layer applied over a dead cell of the photovoltaic device;

FIG. 5 shows a top view of the exemplary photovoltaic device of FIG. 4 having an insulating layer on the photovoltaic cells;

FIG. 6 shows a top view of the exemplary photovoltaic device of FIG. 5 with a conductive strip applied on the insulating strip;

FIG. 7 shows a top view of the exemplary photovoltaic device of FIG. 6 with the conductive strip severed;

FIG. 8 shows a top view of the exemplary photovoltaic device of FIG. 7 with a bus bar applied to the terminal live cell of the photovoltaic device; and,

FIG. 9 shows a flow diagram of an exemplary method of forming the photovoltaic device of FIG. 1.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless expressly stated otherwise. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

A thin film photovoltaic device is generally provided where the contact material for its dead cell is a solder material that collects the charge from the back contact to an electrical lead (e.g., a foil ribbon). The solder layer is generally thicker (in the z-direction) than the back contact, and therefore can carry the electrical charge (i.e., current) without added series resistance. Additionally, since solder material can be applied precisely, especially when compared to bus tape, and takes up less width on the cell, the dead cell area (i.e., its size in the x-y plane of the device) can be minimized, increasing the available area for live cells. Thus, the current collected from the module may be increased if the live cells are widened, or the voltage may be increased if an additional cell is added.

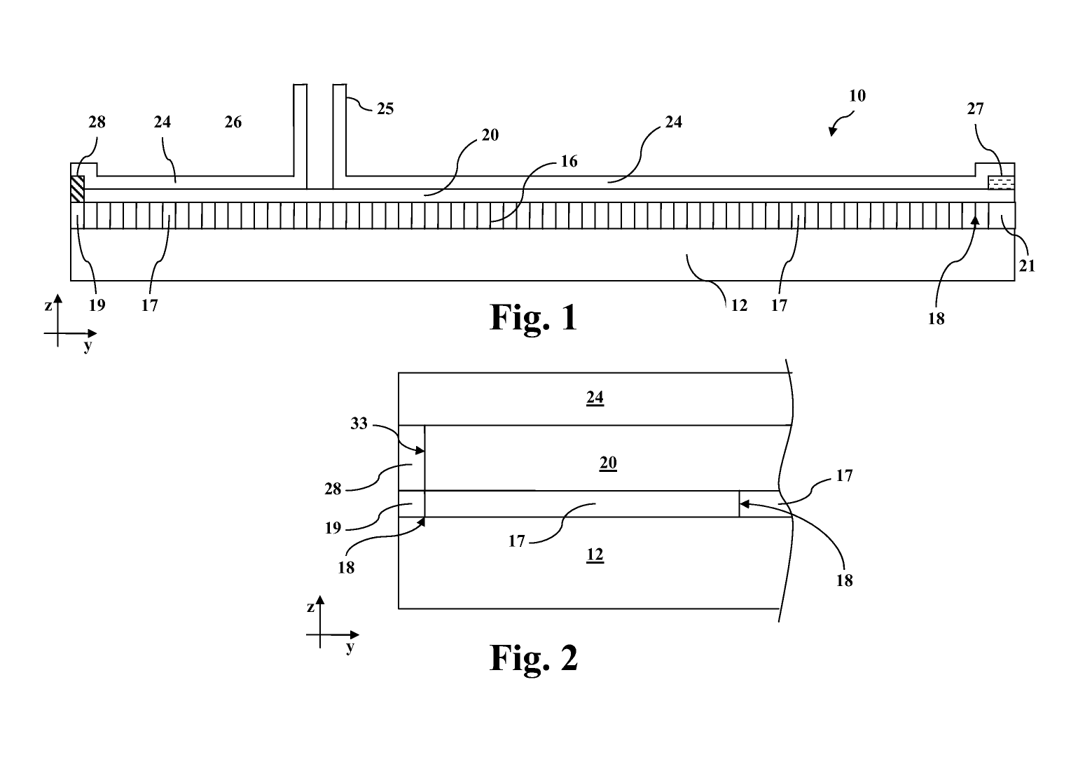

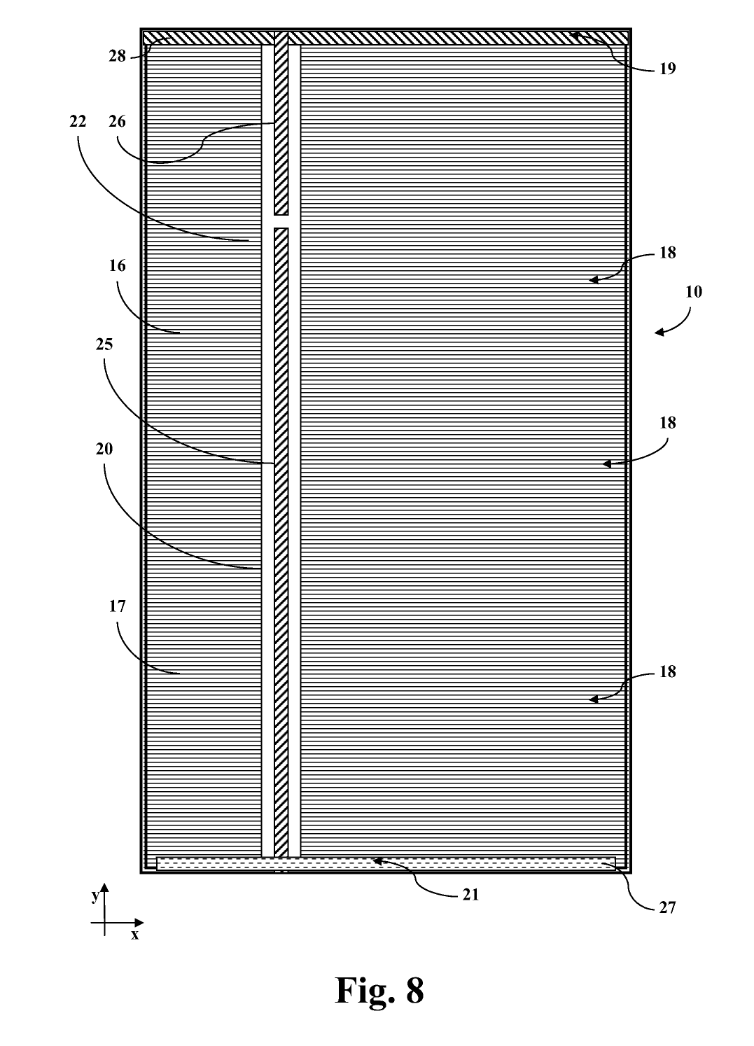

FIG. 1 generally shows a cross-sectional view of an exemplary thin film photovoltaic device 10, in which the cross section is taken where the insulating tape 20 and conductive strip 24 are present on the device (see also, FIG. 8). A solder layer 28 is shown over a dead cell 19, and a bus bar 27 is shown over a terminal cell 21 on the opposite side of the device 10, as explained in greater detail below. It is noted that the configurations shown in the FIGS. are not to scale, unless otherwise noted as to the relative dimensions of the elements.

FIG. 2 shows a blown-up section of the device 10 of FIG. 1 with greater detail of the dead cell 19 and the solder layer 28. As shown, in FIG. 2 the solder layer 28 is positioned over the dead cell 19. The dead cell 19 is shown to be smaller in the y-direction (i.e., in the direction extending the width of the cells 17). As such, the available surface area of the solar cells 17 (i.e., defined in the plane of the x, y directions) can be increased without having to sacrifice the electrical connection to the dead cell. For example, the dead cell 19 can have a width of about 15% to about 75% of the PV cells 17 (e.g., about 25% to about 50% of the width).

In order to not add additional series resistance to the solar module 10, the solder layer 28 must have a resistance that is at most equivalent to that of the back contact of the thin film layers 16. If the active width of the module 10 is defined as x, then the solder layer 28 needs to only carry the current over half the width of the module (i.e., x/2). Then, if the active length of the module 10 is defined as y and the resistivity of the solder layer 28 is defined as rho with a cross sectional area defined by A, where A is the thickness of the solder layer 28 in the z direction times the length of the dead cell 19, and the resistivity of the back contact is defined as rho′ with a cross sectional area defined by A′, where A′ is the thickness of the back contact times the width of each cell 17, in order for the solder layer 28 to have equivalent resistance to the back contact, the following equation must be obeyed.

(rho/A)/(rho′/A′)<y/(x/2)

Any combination of resistance, rho (determined by material choice), width of the dead cell 19, or thickness of the solder layer 28 in the z-direction can be used to achieve this ratio. A more conductive material is most desirable, as a wider dead cell takes off active area of the module 10.

The solder layer 28 is electrically connected to the conductive strip 24, which forms the lead 26 upon severing. For example, the solder layer 28 can be physically connected to the conductive strip 24, and may be positioned under the conductive strip 24, as shown. Alternatively, the solder layer 28 may be positioned over the conductive strip 24. The insulating layer 20 may cover only a portion of, or none of, the solder layer 28, to ensure that sufficient contact between the solder layer 28 and the conductive strip 24 exists.

The solder layer 28 can generally include any suitable solder material, including but not limited to, tin, lead, antimony, bismuth, indium, silver, copper, cadmium, or alloys thereof. Generally, the solder material may be configured to melt at a solder temperature of about 150° C. to about 250° C. (e.g., a soft solder) to ensure that melting the solder can occur without significantly affecting the other components of the device 10. Both lead-based solders and non-lead-based solders may prove useful for this application.

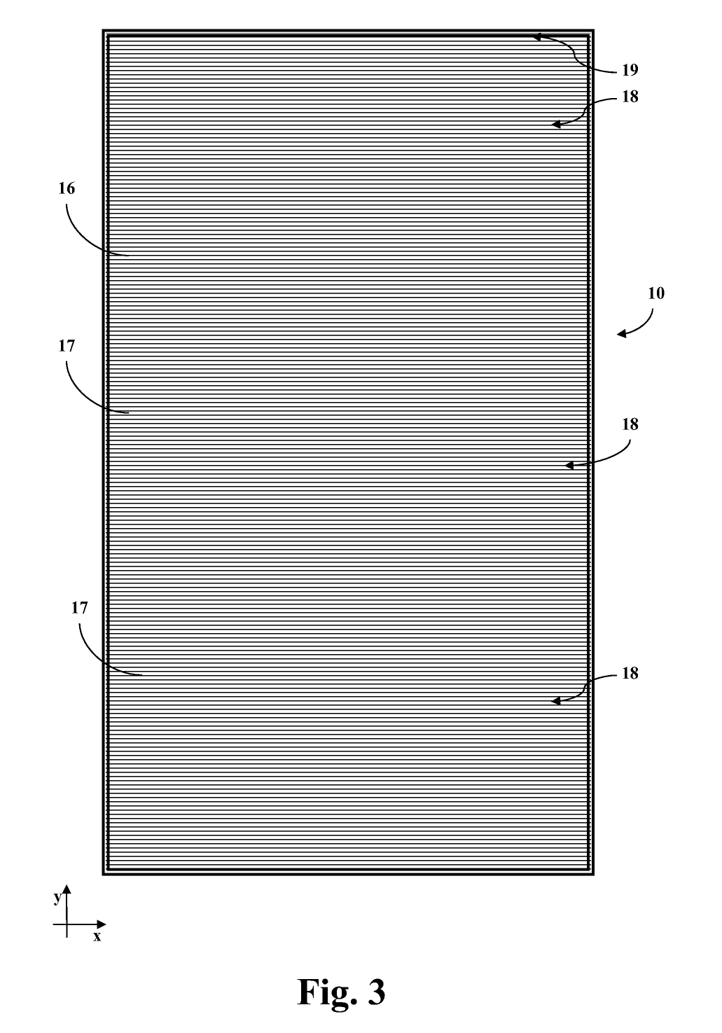

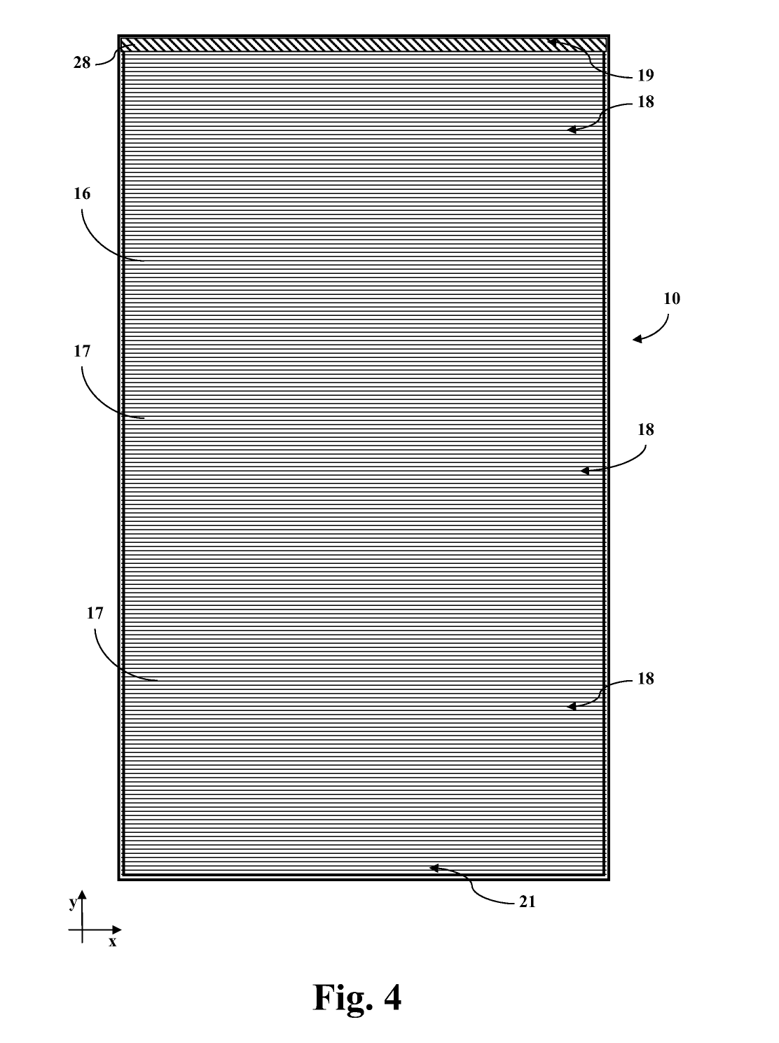

Referring to FIG. 2 in particular, at the point of electrical contact between the conductive strip 24 and solder layer 18, the conductive strip 24 extends past the end 30 of the insulation layer 20 and is in direct electrical contact against the solder layer 18. For example, referring to FIGS. 3-8, the insulation layer 20 may be the first component that is applied along the longitudinal length of the PV module 10 from the terminal cell 21 to the dead cell 19 at the opposite end of the module 10. This layer 20 may have a length so as not to extend completely across the dead cell 19 and/or the terminal cell 21. For example, as seen in FIG. 2, the end 33 of the insulation layer 20 may extend to the scribe line 18 that defines the boundary of the dead cell 19, or may extend slightly onto the dead cell 19. The conductive member 24 (e.g., in the form of a conductive foil ribbon) is then aligned on and attached to the insulation layer 20. The conductive member 24 extends past the end 33 of the insulation layer 20 so as to eventually be pressed directly against the surface of the solder layer 28 (if applied after the solder layer 28) or directly against the back contact of the dead cell 19 (if applied before the solder layer 28). In either configuration, upon heating and melting of the solder layer 28, an electrical connection is secured between the solder layer 28 and the conductive strip 24.

The photovoltaic device 10 generally includes a transparent substrate 12 (e.g., a glass substrate). In this embodiment, the glass 12 can be referred to as a “superstrate,” as it is the substrate on which the subsequent layers are formed even though it faces upward to the radiation source (e.g., the sun) when the cadmium telluride thin film photovoltaic device 10 is in use. The top sheet of glass 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the glass 12 can be a low iron float glass containing less than about 0.015% by weight iron (Fe), and may have a transmissiveness of about 0.9 or greater in the spectrum of interest (e.g., wavelengths from about 300 nm to about 900 nm). In another embodiment, borosilicate glass may be utilized so as to better withstand high temperature processing. An encapsulating substrate (not shown) can be oppositely positioned on the device 10 and can define a connection aperture providing access to the underlying components (e.g., the leads 25, 26) to collect the DC electricity generated by the photovoltaic device 10. In one particular embodiment, the encapsulating substrate is a glass substrate.

A plurality of thin film layers 16 are positioned on the glass substrate 12. The plurality of thin film layers 16 define individual solar cells 17 (also referred to as photovoltaic cells) separated by scribes 18 to collectively form a plurality of serially connected solar cells. Specifically, the individual photovoltaic cells 17 are electrically connected together in series. The plurality of serially connected solar cells 17 are between a dead cell 19 and a terminal cell 21. As shown, the dead cell 19 and the terminal cell 21 are positioned on opposite ends of the plurality of serially connected solar cells 17. The back contact of the dead cell 19 serves as an electrical connector for the device 10, while the TCO layer of the terminal cell 21 serves as the opposite electrical connector for the device 10. As such, the dead cell 19 does not produce a charge in the thin film layers 16, while the terminal cell 21 may.

In one particular embodiment, the plurality of thin film layers can include a transparent conductive oxide layer (e.g., cadmium stannate or a stoichiometric variation of cadmium, tin, and oxygen; or doped tin oxide, etc.) on the glass substrate 12, a resistive transparent buffer layer (e.g., a combination of zinc oxide and tin oxide) on the transparent conductive oxide layer, an n-type layer on the resistive transparent buffer layer, a p-type layer on the n-type layer, and a back contact on the p-type layer. The n-type layer can include cadmium sulfide (i.e., a cadmium sulfide thin film layer), and the p-type layer can include cadmium telluride (i.e., a cadmium telluride thin film layer). Generally, the back contact defines the exposed surface of the thin film layers 16, and serves as an electrical contact for the thin film layers 16 opposite the front contact, as defined by the transparent conductive oxide layer.

For instance, FIG. 3 generally shows a top view of an exemplary thin film photovoltaic device 10 defining a plurality of photovoltaic cells 17 separated by scribes 18. The scribes 18 can be, in one embodiment, substantially parallel to each other such that the photovoltaic cells 17 are substantially the same size. As shown, each of the scribes 18 is generally oriented in the x-direction.

An insulating layer 20 is on the thin film layers 16 to protect the back contact of the thin film layers 16, as shown in FIG. 1. The insulating layer 20 generally includes an insulating material that can prevent electrical conductivity therethrough. Any suitable material can be used to produce the insulating layer 20. In one embodiment, the insulating layer 20 can be an insulating polymeric film coated on both surfaces with an adhesive coating. The adhesive coating can allow for adhesion of the insulating layer 20 to the underlying thin film layers 16 and for the adhesion of the conductive strip 24 to the insulating layer 20. For example, the insulating layer 20 can include a polymeric film of polyethylene terephthalate (PET) having an adhesive coating on either surface. The adhesive coating can be, for example, an acrylic adhesive, such as a thermosetting acrylic adhesive.

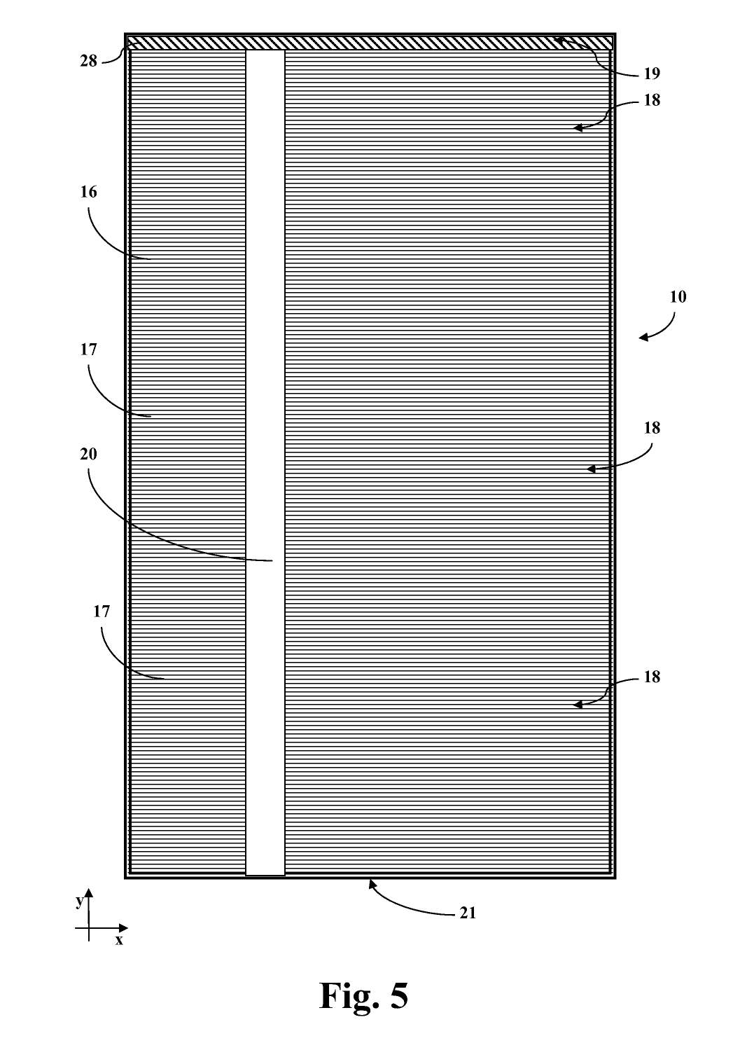

In one particular embodiment, the insulating layer 20 is a strip of insulating material generally oriented in a direction perpendicular to the orientation of the scribes 18. For example, as shown in FIG. 5, the insulating layer 20 can be generally oriented in the y-direction that is perpendicular to the orientation of the scribes 18 in the x-direction.

The insulating layer 20 can have a thickness in the z-direction suitable to prevent electrical conductivity from the underlying thin film layers, particularly the back contact, to any subsequently applied layers. In one particular embodiment, the insulating layer 20 can prevent electrically conductivity between the thin film layers 16 and the conductive strip 24.

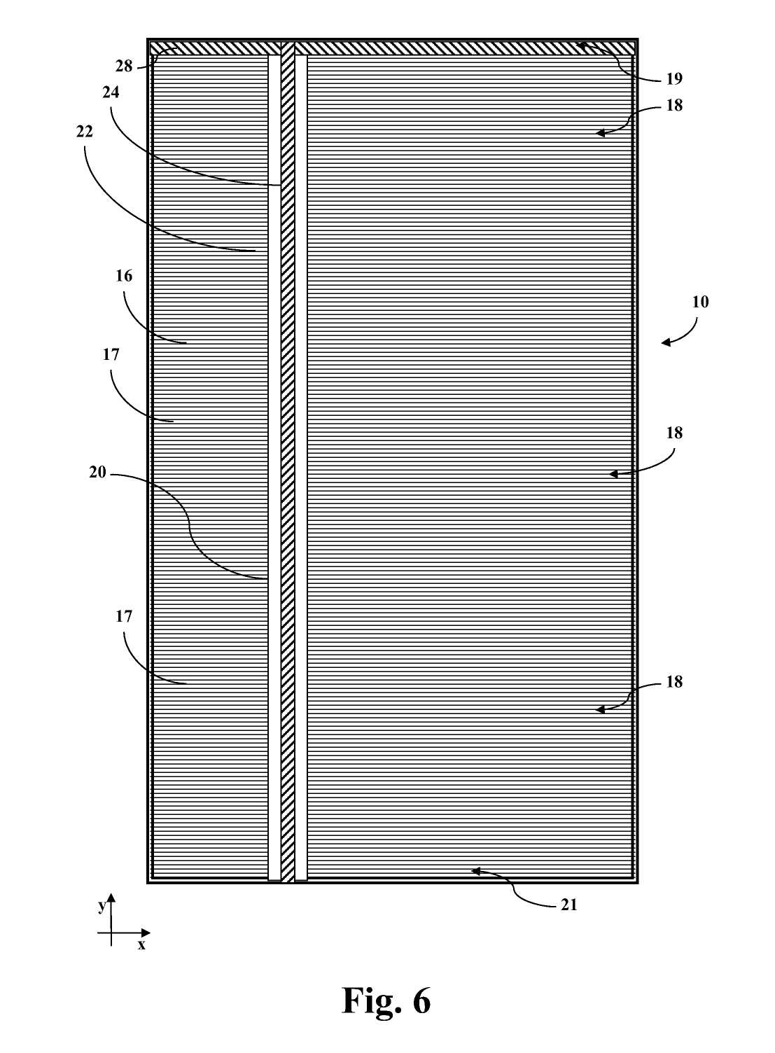

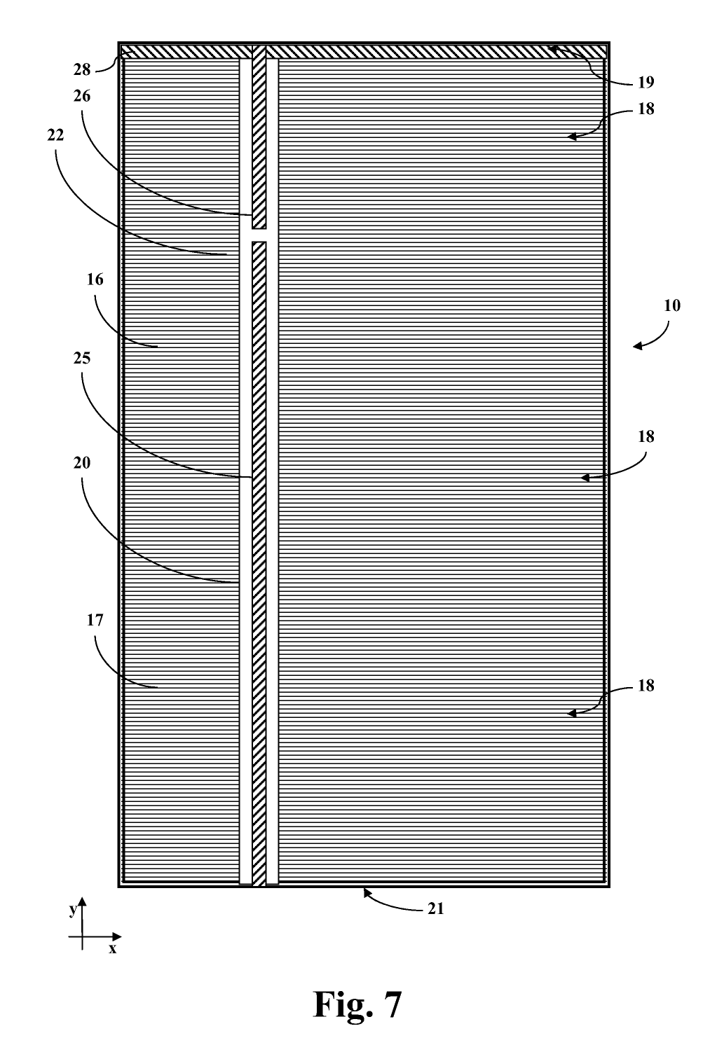

A conductive strip 24, in one embodiment, can be applied as a continuous strip over the insulating layer 20, as shown in FIG. 6. Then, the continuous strip 24 can then be severed to produce a first lead 25 and a second lead 26, as shown in FIG. 1 and FIG. 7. The conductive strip 24 can be constructed from any suitable material. In one particular embodiment, the conductive strip 24 is a strip of metal foil. For example, the metal foil can include a conductive metal.

A bus bar 27 can then be attached over the terminal cell 21 of the photovoltaic device 10 to serve as an opposite electrical connection to the solder layer 28 (e.g., positive and negative) on the photovoltaic device 10. Generally, the conductive strip 24 electrically connects the bus bar 27 to the second lead 26.

The encapsulating substrate (not shown) can be adhered to the photovoltaic device 10 via an adhesive layer (not shown). The adhesive layer is generally positioned over the conductive strip 24, insulating layer 20, and any remaining exposed areas of the thin film layers 16. For example, the adhesive layer can define an adhesive gap that generally corresponds to a connection aperture defined by the encapsulating substrate. As such, the first lead 25 and second lead 26 can extend through the adhesive gap. The adhesive layer can generally protect the thin film layers 16 and attach the encapsulating substrate 14 to the device 10. The adhesive layer can be constructed from ethylene vinyl acetate (EVA), polyvinyl butyral (PVB), silicone based adhesives, or other adhesives which are configured to prevent moisture from penetrating the device.

A junction box (not shown) can also be included in the device and can be configured to electrically connect the photovoltaic device 10 by completing the DC circuit.

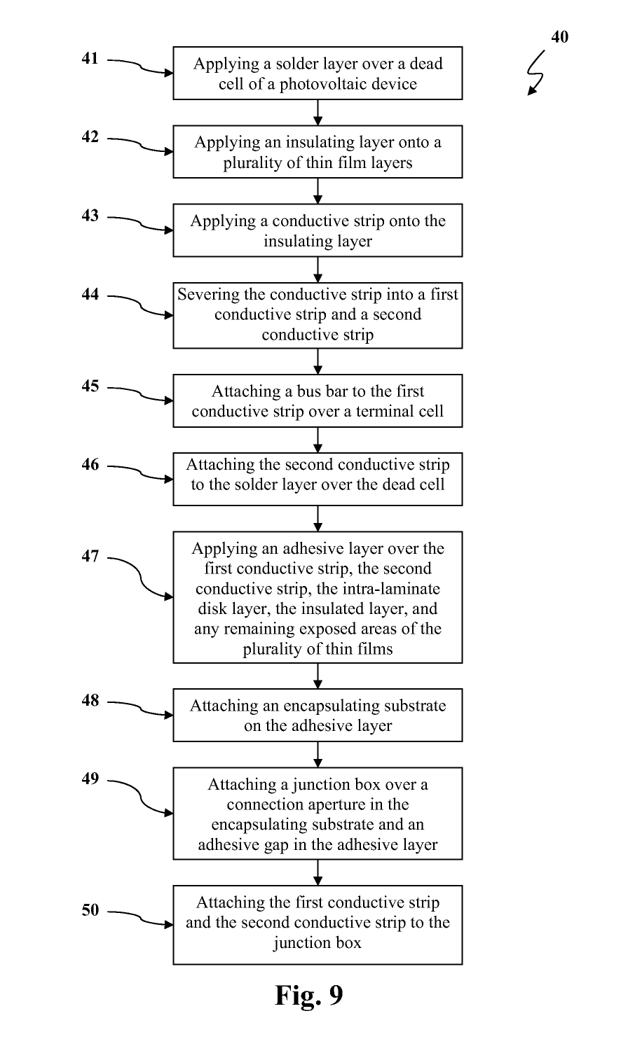

FIG. 9 generally shows a flow diagram of one exemplary method 40 for construction of the exemplary photovoltaic device 10 of FIGS. 1 and 8. According to this method, a solder layer is applied over a dead cell of a photovoltaic device at 41. An insulating layer is applied on plurality of thin film layers at 42. A conductive strip can then be applied on the insulating layer at 43, and severed into a first conductive strip and a second conductive strip at 44. A bus bar can be attached to the first conductive strip and positioned over the terminal cell of the device at 45, while the second conductive strip can be attached to the solder layer. For instance, steps 41-45 of method 40 are exemplified sequentially in FIGS. 3-8.

Method 40 may also include attaching an adhesive layer, defining an adhesive gap for extending the leads therethrough, over the first conductive strip, the second conductive strip, the intra-laminate disk layer, the insulated layer, and any remaining exposed areas of the plurality of thin films at 47. An encapsulating substrate, defining a connection aperture for extending the leads therethrough, can be attached on the adhesive layer at 48. A junction box can be attached over the connection aperture and the adhesive gap at 49, and attached to the first conductive strip and the second conductive strip at 50.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A photovoltaic device, comprising:
a substrate having a plurality of serially connected solar cells defined thereon, wherein the plurality of serially connected solar cells are positioned between a dead cell and a terminal cell for collecting the charge generated by the plurality of serially connected solar cells;
a solder layer applied along the dead cell and connected to a first lead, wherein the solder layer comprises a solder; and,
an electrical connector applied along the terminal cell and connected to a second lead.

2. The photovoltaic device as in claim 1, wherein said electrical connector comprises a bus tape.

3. The photovoltaic device as in claim 1, wherein the dead cell defines less surface area on the photovoltaic module than defined by an individual solar cell in the plurality of serially connected solar cells.

4. The photovoltaic device as in claim 1, wherein each individual solar cell defines a cell width that is less than a width defined by the dead cell.

5. The photovoltaic device as in claim 1, wherein the solder comprises at least one of tin, lead, antimony, bismuth, silver, or indium.

6. The photovoltaic device as in claim 1, wherein said first lead and said second lead are formed from a severed foil ribbon.

7. The photovoltaic device as in claim 1, further comprising:
an insulating layer beneath said first lead and said second lead.

8. The photovoltaic device as in claim 7, wherein the dead cell defines a width, and wherein the insulating layer does not extend over the entire width of the dead cell.

9. The photovoltaic device as in claim 8, wherein the insulating layer does not extend over the dead cell.

10. The photovoltaic device as in claim 8, wherein the solder layer extends over the insulating layer.

11. A method of manufacturing a photovoltaic device, the method comprising:
applying a solder layer on a dead cell positioned at an end of a plurality of serially connected solar cells defined on a substrate, wherein the plurality of serially connected solar cells are positioned between the dead cell and a terminal cell for collecting the charge generated by the plurality of serially connected solar cells, and, wherein the solder layer comprises a solder;
connecting the solder layer to a first lead; and,
connecting the terminal cell to an electrical connector to a second lead.

12. The method as in claim 11, wherein said electrical connector comprises a bus tape.

13. The method as in claim 11, wherein the dead cell defines less surface area on the photovoltaic module than defined by an individual solar cell in the plurality of serially connected solar cells.

14. The method as in claim 11, wherein each individual solar cell defines a cell width that is less than a width defined by the dead cell.

15. The method as in claim 11, wherein the solder comprises at least one of tin, lead, antimony, bismuth, silver, or indium.

16. The method as in claim 11, further comprising:
severing a foil ribbon to form the first lead and the second lead.

17. The method as in claim 11, further comprising:
applying an insulating layer beneath the first lead and the second lead.

18. The method as in claim 17, wherein the dead cell defines a width, and wherein the insulating layer does not extend over the entire width of the dead cell.

19. The method as in claim 18, wherein the insulating layer does not extend over the dead cell.

20. The method as in claim 17, wherein the solder is placed over the insulating layer.
